(19) United States
(12) Patent Application Publication
(10) Pub. No.: US 2026/0052683 A1
(43) Pub. Date: Feb. 19, 2026

(54) ENHANCED ELECTROMIGRATION STORAGE DEVICE FOR NON-VOLATILE MEMORY

(71) Applicant: eMemory Technology Inc., Hsin-Chu (TW)

(72) Inventors: Chia-Chou LIN, Hsinchu County (TW); Ping-Lung Ho, Hsinchu County (TW)

(21) Appl. No.: 19/296,982

(22) Filed: Aug. 12, 2025

Related U.S. Application Data
(60) Provisional application No. 63/682,344, filed on Aug. 13, 2024.

(51) Int. Cl. H10B 20/25

(52) U.S. Cl. CPC H10B 20/25

(57) ABSTRACT

An enhanced electromigration storage device for a non-volatile memory is provided. When a program action is performed, two different voltages are simultaneously provided to the gate terminal of a FinFET transistor or a GAA transistor. Furthermore, the threshold of the FinFET transistor or the GAA transistor is changed according to the electromigration mechanism. Consequently, the storage device is selectively in a programmed state or an unprogrammed state. When the read action is performed, the same voltage is provided to the gate terminal of the FinFET transistor or the GAA transistor, and the storage state of the storage device is determined according to the read current generated by the FinFET transistor or the GAA transistor.

This application claims the benefit of U.S. provisional application Ser. No. 63/682,344, filed Aug. 13, 2024, the subject matters of which are incorporated herein by references.

### FIELD OF THE INVENTION

The present invention relates to a non-volatile memory, and more particularly to an enhanced electromigration storage device for a non-volatile memory.

### BACKGROUND OF THE INVENTION

As is well known, non-volatile memories (MVMs) have been widely used in a variety of electronic devices such as SD cards or solid state drives (SSDs). Generally, a non-volatile memory includes a memory cell array. The memory cell array includes a plurality of memory cells. Each memory cell includes a storage device. For example, the storage device is an antifuse-type transistor.

The storage state of the antifuse-type transistor can be determined according to the status of a gate dielectric layer of the antifuse-type transistor. In case that the gate dielectric layer of the antifuse-type transistor is not ruptured, the storage device is in the first storage state. When the memory cell is subjected to the program action, the gate dielectric layer of the antifuse-type transistor is ruptured. Consequently, the storage device is in the second storage state. After the gate dielectric layer of the antifuse-type transistor is ruptured, the storage device cannot be restored to the first storage state.

For example, an one time programming memory cell with fin field-effect transistor using physically unclonable function technology is disclosed in U.S. Pat. No. 12,289,883 B2. The storage device of the memory cell is a fin field-effect transistor (referred hereinafter as a FinFET transistor). As shown in FIG. 1A, it is a schematic perspective view illustrating a FinFET transistor. FIG. 1B is a schematic top view of the FinFET transistor. FIG. 1C is a schematic cross-sectional view of the FinFET transistor taken along the line AB. The FinFET transistor M_{FIN} includes: a gate structure, drain/source contact layers 130 and 140, and fins 112, 114, 116 and 118.

The gate structure is formed over the isolation layer 110. The gate structure covers the central regions of the fins 112, 114, 116 and 118. The gate structure includes a gate conductive layer 120, and gate dielectric layers 122, 124, 126 and 128. The gate dielectric layers 122, 124, 126 and 128 respectively cover the top surfaces and the lateral surfaces of the central region of the fins 112, 114, 116 and 118. The gate conductive layer 120 covers the gate dielectric layers 122, 124, 126 and 128. Furthermore, the drain/source contact layer 130 is contacted with a first side region of the fins 112, 114, 116 and 118. The drain/source contact layer 140 is contacted with a second side region of the fins 112, 114, 116 and 118.

The conductive layer 120 is served as a gate terminal of the FinFET transistor M_{FIN}. The drain/source contact layer 130 is served as a first drain/source terminal of the FinFET transistor M_{FIN}. The drain/source contact layer 140 is served as a second drain/source terminal of the FinFET transistor M_{FIN}. Of course, the number of fins in the FinFET transistor M_{FIN} is unlimited, as long as the number of fins is greater than or equal to one. Furthermore, two FinFET transistors can have various connections.

FIG. 2 is a schematic diagram of two FinFET transistors. Compared to the FinFET transistor M_{FIN} in FIG. 1A, in FIG. 2, the drain/source contact layer 130 is contacted with the first side region of the fins 112 and 114, the drain/source contact layer 140 is contacted with the second side region of the fins 112 and 114, the drain/source contact layer 156 is contacted with the first side region of the fins 116 and 118, and the drain/source contact layer 158 is contacted with the second side region of the fins 116 and 118. Furthermore, the drain/source contact layer 130 is not contacted with the drain/source contact layer 156, and the drain/source contact layer 140 is not contacted with the drain/source contact layer 158. Accordingly, two FinFET transistors M_{FIN1} and M_{FIN2} can be formed, wherein each FinFET transistors M_{FIN1} and M_{FIN2} comprises two fins, and the two FinFET transistors M_{FIN1} and M_{FIN2} share the gate conductive layer 120.

Moreover, an antifuse-type one time programming memory cell with gate-all-around is disclosed in US Patent publication No. 2023/0371249 A1. The storage device of the memory cell is a gate-all-around transistor (referred hereinafter as a GAA transistor). As shown in FIG. 3A, it is schematic perspective views illustrating a GAA transistor. FIG. 3B is a schematic top view of the GAA transistor. FIG. 3C is a schematic cross-sectional view of the GAA transistor taken along the line ab. FIG. 3D is a schematic cross-sectional view of the GAA transistor taken along the line cd. The GAA transistor M_{GAA} includes: a gate structure 220, drain/source structure 232 and 236, and a nanowire 230.

The gate structure 220 is formed over the isolation layer 210. The gate structure 220 includes two spacers 252 and 246, a gate dielectric layer 222 and a gate conductive layer 224. The gate dielectric layer 222 surrounds the central region of the nanowire 230. The gate conductive layer 224 surrounds the gate dielectric layer 222. The gate conductive layer 224 is also disposed on the isolation layer 210. The first side region of the nanowire 230 is surrounded by the spacer 252. The second side region of the nanowire 230 is surrounded by the spacer 246. The spacers 252 and 246 are formed on the semiconductor substrate sub. Furthermore, the drain/source structure 232 is electrically contacted with a first terminal of the nanowire 230, and the drain/source structure 236 is electrically contacted with a second terminal of the nanowire 230.

The conductive layer 224 is served as a gate terminal of the GAA transistor M_{GAA}. The drain/source structure 232 is served as a first drain/source terminal of the GAA transistor M_{GAA}. The drain/source structure 236 is served as a second drain/source terminal of the GAA transistor M_{GAA}. Of course, the number of nanowires in the GAA transistor M_{GAA} is unlimited, as long as the number of nanowires is greater than or equal to one. Furthermore, two GAA transistors can have various connections.

FIG. 4 is a schematic diagram of two GAA transistors. Compared to the GAA transistor M_{GAA} in FIG. 3A, in FIG. 4, the gate structure 220 further includes a gate dielectric layers 284. A nanowire 290 is penetrated through the gate structure 220, the gate dielectric layer 284 surrounds the central region of the nanowire 290, and the gate conductive layer 224 surrounds the gate dielectric layer 284. Moreover, the drain/source structure 292 is electrically contacted with a first terminal of the nanowire 290, and the drain/source structure 296 is electrically contacted with a second terminal of the nanowire 290. The drain/source structure 232 is not contacted with the drain/source structure 292, and the drain/source structure 236 is not contacted with the drain/source structure 296. Accordingly, two GAA transistors M_{GAA1} and M_{GAA2} can be formed, wherein each GAA transistors M_{GAA1} and M_{GAA2} comprises one nanowire, and the two GAA transistors M_{GAA1} and M_{GAA2} share the gate conductive layer 224.

When the storage state of the memory cell of the non-volatile memory is changed, it is necessary to receive a higher operating voltage. For example, when the program action is performed on the memory cell, the storage device of the memory cell receives a program voltage (e.g., 8V˜12V), and a program current of about several hundred mA is generated.

Since the program voltage is higher than the supply voltage received by a general IC chip, for example 1.2V, the non-volatile memory is usually equipped with a charge pump to boost the supply voltage to a higher operation voltage. However, the charge pump may occupy a very large layout area of the IC chip.

### SUMMARY OF THE INVENTION

An embodiment of the present invention provides a storage device for a non-volatile memory. The storage device includes a first fin field-effect transistor, a first conducting line and a second conducting line. The first fin field-effect transistor includes a first fin, a gate structure, a first drain/source contact layer and a second drain/source contact layer. The gate structure includes a first gate dielectric layer, a first conductive layer and a second conductive layer. A top surface and two lateral surfaces of a central region of the first fin are covered by the first gate dielectric layer. The first gate dielectric layer is covered by the first conductive layer. The first conductive layer is covered by the second conductive layer. The first drain/source contact layer is electrically contacted with a first side region of the first fin. The second drain/source contact layer is electrically contacted with a second side region of the first fin. The first conducting line located on a first side of the gate structure and electrically connected with a first side of the second conductive layer. The second conducting line is located on a second side of the gate structure and electrically connected with a second side of the second conductive layer. When a program action is performed, the first conducting line receives a first voltage, the second conducting line receives a second voltage, and a program current flows from the first conducting line to the second conducting line through the first conductive layer and the second conductive layer. The first voltage is higher than the second voltage. When a read action is performed, the first drain/source contact layer receives a third voltage, the second drain/source contact layer receives a fourth voltage, the first conducting line and the second conducting line receive a control voltage, and a first read current flows from the first drain/source contact layer to the second drain/source contact layer through a channel region of the fin field-effect transistor, and a storage state is determined the non-volatile memory device is determined by the first read current. The third voltage is higher than the fourth voltage. The difference between the first voltage and the second voltage is equal to a program voltage. The difference between the third voltage and the fourth voltage is equal to a read voltage.

Another embodiment of the present invention provides a storage device for a non-volatile memory. The storage device includes a first gate-all-around transistor, a first conducting line and a second conducting line. The first gate-all-around transistor includes a first nanowire, a gate structure, a first drain/source structure and a second drain/source structure. The gate structure includes a first gate dielectric layer, a first conductive layer and a second conductive layer. A central region of the first nanowire is surrounded by the first gate dielectric layer. The first gate dielectric layer is surrounded by the first conductive layer. The first conductive layer is surrounded by the second conductive layer. The first drain/source structure is electrically contacted with a first side region of the first nanowire. The second drain/source structure is electrically contacted with a second side region of the first nanowire. The first conducting line is located on a first side of the gate structure and electrically connected with a first side of the second conductive layer. The second conducting line is located on a second side of the gate structure and electrically connected with a second side of the second conductive layer. When a program action is performed, the first conducting line receives a first voltage, the second conducting line receives a second voltage, and a program current flows from the first conducting line to the second conducting line through the first conductive layer and the second conductive layer. The first voltage is different from the second voltage. When a read action is performed, the first drain/source structure receives a third voltage, the second drain/source structure receives a fourth voltage, the first conducting line and the second conducting line receive a control voltage, and a first read current flows from the first drain/source structure to the second drain/source structure through a channel region of the gate-all-around transistor, and a storage state is determined the non-volatile memory device is determined by the first read current. The third voltage is different from the fourth voltage. The difference between the first voltage and the second voltage is equal to a program voltage. The difference between the third voltage and the fourth voltage is equal to a read voltage.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1A (prior art) is a schematic perspective view illustrating a FinFET transistor;

FIG. 1B (prior art) is a schematic top view of the FinFET transistor;

FIG. 1C (prior art) is a schematic cross-sectional view of the FinFET transistor taken along the line AB;

FIG. 2 (prior art) is schematic diagram of two FinFET transistors;

FIG. 3A (prior art) is a schematic perspective view illustrating a GAA transistor;

FIG. 3B (prior art) is a schematic top view of the GAA transistor;

FIG. 3C (prior art) is a schematic cross-sectional view of the GAA transistor taken along the line ab;

FIG. 3D (prior art) is a schematic cross-sectional view of the GAA transistor taken along the line cd;

FIG. 4 (prior art) is schematic diagram of two GAA transistors;

FIG. 5A is a schematic cross-sectional view illustrating the gate structure of an enhanced electromigration storage device according to a first embodiment of the present invention;

FIG. 5B is a schematic top view illustrating the enhanced electromigration storage device according to the first embodiment of the present invention;

FIG. 6A schematically illustrate associated bias voltages for performing the program action on the storage device according to the first embodiment of the present invention;

FIG. 6B and FIG. 6C schematically illustrate associated bias voltages for performing a read action on the storage device according to the first embodiment of the present invention;

FIG. 7A is a schematic cross-sectional view illustrating the gate structure of an enhanced electromigration storage device according to a second embodiment of the present invention;

FIG. 7B is a schematic top view illustrating the enhanced electromigration storage device according to the second embodiment of the present invention;

FIG. 8A schematically illustrate associated bias voltages for performing the program action on the storage device according to the second embodiment of the present invention;

FIG. 8B and FIG. 8C schematically illustrate associated bias voltages for performing a read action on the storage device according to the second embodiment of the present invention;

FIG. 9A is a schematic cross-sectional view illustrating the gate structure of an enhanced electromigration storage device according to a third embodiment of the present invention;

FIG. 9B is a schematic top view illustrating the enhanced electromigration storage device according to the third embodiment of the present invention;

FIG. 10A schematically illustrate associated bias voltages for performing the program action on the storage device according to the second embodiment of the present invention;

FIG. 10B and FIG. 10C schematically illustrate associated bias voltages for performing a read action on the storage device according to the third embodiment of the present invention;

FIG. 11A is a schematic cross-sectional view illustrating the gate structure of an enhanced electromigration storage device according to a fourth embodiment of the present invention;

FIG. 11B is a schematic top view illustrating the enhanced electromigration storage device according to the fourth embodiment of the present invention;

FIG. 12A schematically illustrate associated bias voltages for performing the program action on the storage device according to the fourth embodiment of the present invention;

FIG. 12B and FIG. 12C schematically illustrate associated bias voltages for performing a read action on the storage device according to the fourth embodiment of the present invention;

FIG. 13A is a schematic top view illustrating an enhanced electromigration storage device according to a fifth embodiment of the present invention;

FIG. 13B is a schematic top view illustrating an enhanced electromigration storage device according to a sixth embodiment of the present invention;

FIG. 13C is a schematic top view illustrating an enhanced electromigration storage device according to a seventh embodiment of the present invention;

FIG. 13D is a schematic top view illustrating an enhanced electromigration storage device according to an eighth embodiment of the present invention; and

FIG. 13E is a schematic top view illustrating an enhanced electromigration storage device according to a ninth embodiment of the present invention.

### DETAILED DESCRIPTION OF PREFERRED EMBODIMENTS

As known, electromigration (EM) is the transport of material caused by the gradual movement of the ions in a conductor due to the momentum transfer between conducting electrons and diffusing metal atoms. In accordance with the technologies of the present invention, the storage device of the non-volatile memory is designed according to the electromigration mechanism. For example, the storage device is a fin field-effect transistor (referred hereinafter as a FinFET transistor) or a gate-all-around transistor (referred hereinafter as a GAA transistor).

Generally, the threshold voltage of each of the FinFET transistor and the GAA transistor is determined according to the material and thickness of the work function metal layer. The on/off states of each of the FinFET transistor and the GAA transistor are controlled according to the voltage received by the gate terminal of each of the FinFET transistor and the GAA transistor. That is, those skilled in the art would not provide different voltages to the gate terminals of the FinFET transistor and the GAA transistor at the same time.

In accordance with the present invention, the FinFET transistor or the GAA transistor is used as the storage device of the memory cell. When the program action is performed, two different voltages are simultaneously provided to the gate terminal of the FinFET transistor or the GAA transistor. Furthermore, the threshold of the FinFET transistor or the GAA transistor is changed according to the electromigration mechanism. Consequently, the storage device is selectively in the programmed state or the unprogrammed state. When the read action is performed, the same voltage is provided to the gate terminal of the FinFET transistor or the GAA transistor, and the storage state of the storage device is determined according to the read current generated by the FinFET transistor or the GAA transistor.

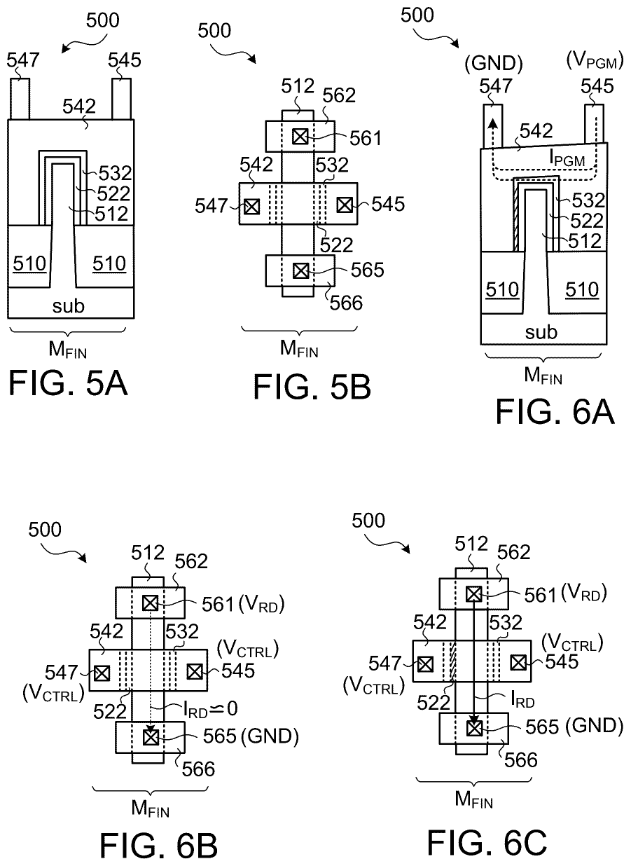

FIG. 5A is a schematic cross-sectional view illustrating the gate structure of an enhanced electromigration storage device according to a first embodiment of the present invention. FIG. 5B is a schematic top view illustrating the enhanced electromigration storage device according to the first embodiment of the present invention. The enhanced electromigration storage device 500 is included in a memory cell of the non-volatile memory. For brevity, the enhanced electromigration storage device 500 is referred hereinafter to as a storage device 500.

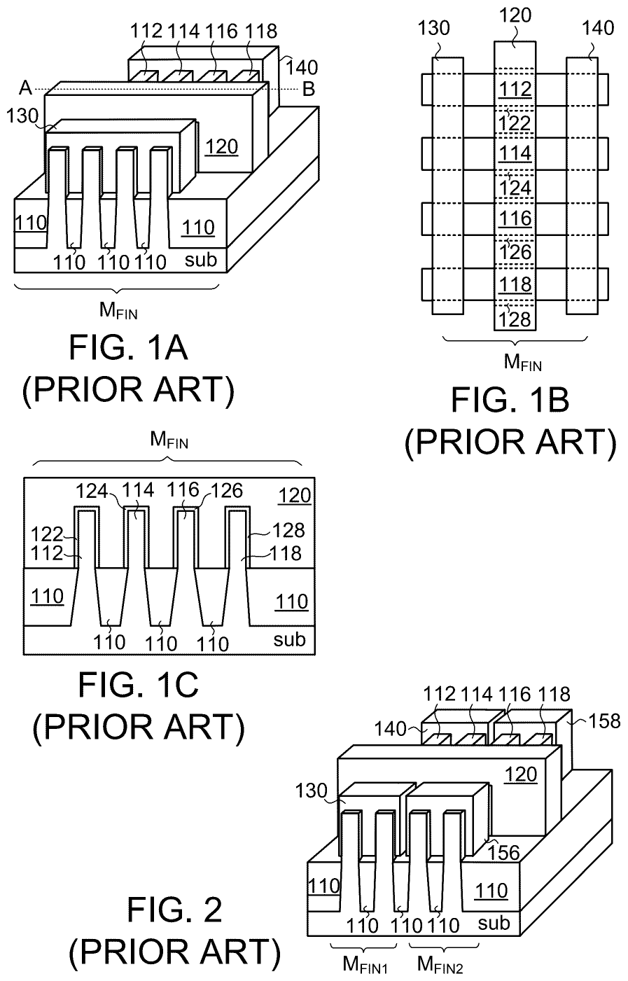

In this embodiment, the storage device 500 includes a FinFET transistor M_{FIN} and two conducting lines 545 and 547. The FinFET transistor M_{FIN} is located over a semiconductor substrate sub and an isolation layer 510. The structure of the FinFET transistor M_{FIN} is similar to that of the FinFET transistor M_{FIN} shown in FIG. 1C, but only one fin 512 is provided. It is noted that the number of fins in the FinFET transistor M_{FIN} of the storage device 500 is not restricted. The FinFET transistor M_{FIN} includes a fin 512, a gate structure and two drain/source contact layers 562 and 566. The gate structure includes a gate dielectric layer 522 and two conductive layers 532 and 542. The gate dielectric layer 522 covers the top surface and the lateral surface of the central region of the fin 512. The conductive layer 532 covers the gate dielectric layer 522. The conductive layer 542 covers the conductive layer 532. That is, the gate conductive layer of the FinFET transistor M_{FIN} is formed by the two conductive layers 532 and 542. The conductive layer 532 is a work function metal layer. For example, the material of the conductive layers 532 is titanium nitride (TiN), tantalum nitride (TaN), or titanium-aluminum alloy (TiAl). The conductive layer 542 may be of the same material as the conductive layer 532.

The conducting line 545 is formed on the first side of the gate structure. In addition, the conducting line 545 is electrically connected with the first side of the conductive layer 542. The conducting line 547 is formed on the second side of the gate structure. In addition, the conducting line 547 is electrically connected with the second side of the conductive layer 542. In an embodiment, contact holes are formed in the first side and the second side of the conductive layer 542. After a metallic material is filled into the contact holes, the conducting lines 545 and 547 are formed. Similarly, a conducting line 561 is formed to be electrically connected with a drain/source contact layer 562, and a conducting line 565 is formed to be electrically connected with a drain/source contact layer 566.

In accordance with a feature of the present invention, the electromigration mechanism is used to perform the program action. When the program action is performed, two different voltages are respectively provided to the two conducting lines 545 and 547. Consequently, a program current is generated in the region between the two conducting lines 545 and 547. Since electrons in the program current flow between the conductive layers 542 and 532, the conductive layer 532 gradually migrates in the direction opposite to the electric field. In other words, the thickness of the conductive layer 532 is subject to a change. The use of the electromigration mechanism results in the thickness change of the work function metal layer. Consequently, the threshold voltage of the FinFET transistor M_{FIN} is changed.

Furthermore, when the program action is performed, no bias voltage is provided to the drain/source contact layers 562 and 566. In other words, when the program action is performed, the conducting line 561 and the conducting line 565 are in a floating state.

FIG. 6A schematically illustrate associated bias voltages for performing the program action on the storage device according to the first embodiment of the present invention. Before the program action is performed, the storage device 500 is in the unprogrammed state. When the program action is performed, two different voltages are respectively provided to the two conducting lines 545 and 547. For example, a program voltage V_{PGM} is provided to the conducting line 545, and a ground voltage GND is provided to the conducting line 547. Consequently, the voltage difference between the two conducting lines 545 and 547 is equal to the program voltage V_{PGM}. Under this circumstance, the conducting line 545 is regarded as the anode, and the conducting line 547 is regarded as the cathode. Consequently, the program current I_{PGM} flows between the conductive layers 532 and 542.

As shown in FIG. 6A, the program current I_{PGM} indicated by the dotted line flows from the conducting line 545 to the conducting line 547 through the conductive layers 532 and 542. Generally, the electromigration starts from the cathode (i.e., the conducting line 547). Due to the electromigration mechanism, the metal ions in the conductive layers 532 and 542 close to the cathode migrate in the opposite direction of the electric field (i.e., to the right). After the program action is completed, the thickness of the conductive layer 532 on the left side and indicated by the slash lines becomes thinner. Consequently, the threshold voltage of the FinFET transistor M_{FIN} is changed, and the storage state of the storage device 500 is changed to the programmed state. For example, before the program action, the threshold voltage of the FinFET transistor M_{FIN} is 0.5V. After the program action is completed, the threshold voltage of the FinFET transistor M_{FIN} is changed to 0.3V.

In an embodiment, when the program current I_{PGM} is greater than 100 microamperes (μA), the threshold voltage of the FinFET transistor M_{FIN} is changed by about 0.2˜0.3V. Since the resistance values of the conductive layers 532 and 542 are very low, the program voltage V_{PGM} is very low. For example, the program voltage V_{PGM} of about 1.5V to 2.5V is feasible for the program action. When compared with the program action of the conventional non-volatile memory requiring a higher program voltage (e.g., 8V˜12V), the storage device 500 of the present invention are more advantageous. For example, the program voltage and the program current are lower. In other words, it is not necessary to provide such high program voltage V_{PGM} to the non-volatile memory with the storage device 500 of the present invention. Since there is no need to design a charge pump for the higher program voltage V_{PGM} in the non-volatile memory, the overall layout area of the non-volatile memory can be greatly reduced.

FIG. 6B and FIG. 6C schematically illustrate associated bias voltages for performing a read action on the storage device according to the first embodiment of the present invention. In FIG. 6B, the storage device 500 is in the unprogrammed state. For example, the threshold voltage of the FinFET transistor M_{FIN} is 0.5V. In FIG. 6C, the storage device 500 is in the programmed state. For example, the threshold voltage of the FinFET transistor M_{FIN} is 0.3V.

When a read action is performed on the storage device 500, the same control voltage V_{CTRL} is provided to the two conducting lines 545 and 547, and no current is generated between the two conducting lines 545 and 547. In addition, two different voltages are simultaneously provided to the two conducting lines 561 and 565. For example, a read voltage V_{RD} is provided to the conducting line 561, and the ground voltage GND is provided to the conducting line 565. Consequently, the voltage difference between the two conducting lines 561 and 565 is equal to the read voltage V_{RD}. For example, the read voltage V_{RD} is 1.0V.

When the read action is performed, the control voltage V_{CTRL} is set to 0.4V, and the control voltage V_{CTRL} is provided to the two conducting lines 545 and 547, and no current is generated between the two conducting lines 545 and 547. In FIG. 6B, the control voltage V_{CTRL} is lower than the threshold voltage of the FinFET transistor M_{FIN} (0.5V). Consequently, the FinFET transistor M_{FIN} is turned off, and the read current I_{RD} between the two conducting lines 561 and 565 is very low (nearly zero). In FIG. 6C, the control voltage V_{CTRL} is higher than the threshold voltage of the FinFET transistor M_{FIN} (0.3V). Consequently, the FinFET transistor M_{FIN} is turned on, and the read current I_{RD} generated by the FinFET transistor M_{FIN} is higher. The read current I_{RD} flows from the conducting line 561 to the conducting line 565 through the drain/source contact layer 562, the channel region of the FinFET transistor M_{FIN} and the drain/source contact layer 566. In some embodiments, when the read action is performed, the control voltage V_{CTRL} is provided to one of the two conducting lines 545 and 547, and another one of the two conducting lines 545 and 547 is floating.

Furthermore, a sensing circuit can be used to determine the storage state of the storage device. For example, the non-volatile memory is equipped with a current comparator (not shown), and the current comparator is used as the sensing circuit. The first input terminal of the current comparator receives the read current I_{RD}. The second input terminal of the current comparator receives a reference current I_{REF}. The output terminal of the current comparator generates an output signal. If the magnitude of the read current I_{RD} is higher than the magnitude of the reference current I_{REF}, the current comparator generates an output signal with a first logic level, indicating that the storage device 500 is in the programmed state. Whereas, if the magnitude of the read current I_{RD} is lower than the magnitude of the reference current I_{REF}, the current comparator generates an output signal with a second logic level, indicating that the storage device 500 is in the unprogrammed state. Since the read current I_{RD} generated by the FinFET transistor M_{FIN} in FIG. 6B is very low (nearly zero), the sensing circuit determines that the storage device 500 is in the unprogrammed state. Since the read current I_{RD} generated by the FinFET transistor M_{FIN} in FIG. 6C is higher, the sensing circuit determines that the storage device 500 is in the programmed state.

In a variant example, the non-volatile memory is equipped with a reference memory cell. The reference memory cell includes a reference storage device. The structure of the reference storage device is similar to that of the storage device shown in FIG. 5A. The reference storage device can be selectively in the unprogrammed state or the programmed state. When the read action is performed, the reference storage device receives the control voltage V_{CTRL} and the read voltage V_{RD}, and the reference storage device generates the reference current I_{REF}.

Similarly, the sensing circuit of the non-volatile memory receives the read current I_{RD} and the reference current I_{REF}. In addition, the sensing circuit determines the storage state of the storage device according to the difference between the read current I_{RD} and the reference current I_{REF}.

For example, it is assumed that the reference storage device is in the unprogrammed state. If the difference between the read current I_{RD} and the reference current I_{REF} is lower than a specified value, the sensing circuit determines that the storage device is in the unprogrammed state. Whereas, if the difference between the read current I_{RD} and the reference current I_{REF} is higher than the specified value, the sensing circuit determines that the storage device is in the programmed state.

Alternatively, it is assumed that the reference storage device is in the programmed state. If the difference between the read current I_{RD} and the reference current I_{REF} is lower than a specified value, the sensing circuit determines that the storage device is in the programmed state. Whereas, if the difference between the read current I_{RD} and the reference current I_{REF} is higher than the specified value, the sensing circuit determines that the storage device is in the unprogrammed state.

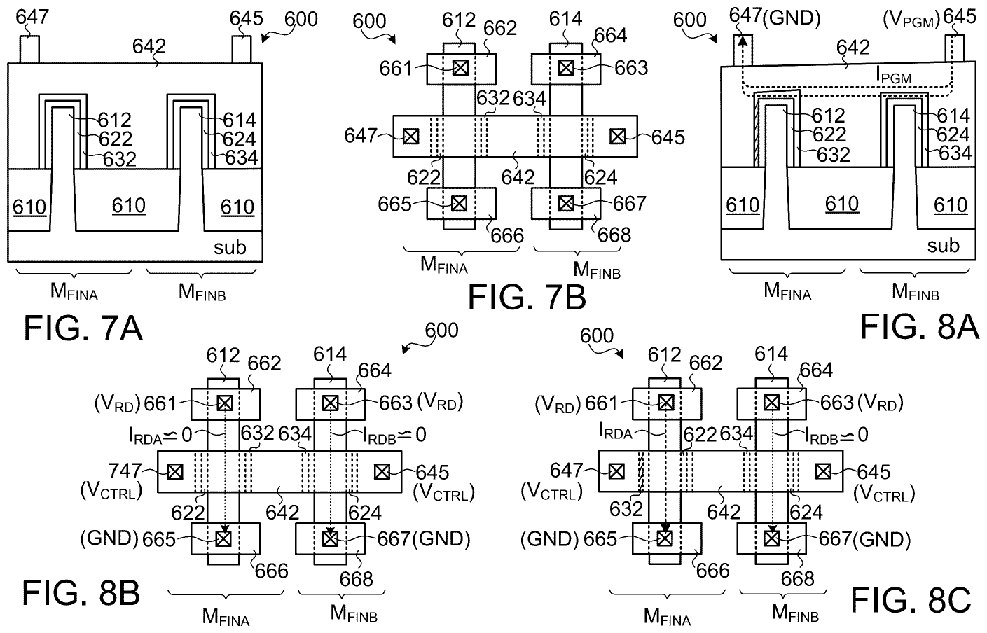

FIG. 7A is a schematic cross-sectional view illustrating the gate structure of an enhanced electromigration storage device according to a second embodiment of the present invention. FIG. 7B is a schematic top view illustrating the enhanced electromigration storage device according to the second embodiment of the present invention. In this embodiment, the storage device 600 includes two FinFET transistor M_{FINA} and M_{FINB}. Furthermore, the storage device 600 is designed in a differential memory cell of the non-volatile memory.

In this embodiment, the storage device 600 includes the FinFET transistor M_{FINA}, the FinFET transistor M_{FINB}, and two conducting lines 645 and 647. The FinFET transistor M_{FINA} and the FinFET transistor M_{FINB} are located over a semiconductor substrate sub and an isolation layer 610. The structures of the FinFET transistor M_{FINA} and the FinFET transistor M_{FINB} are similar to those of the FinFET transistor M_{FIN1} and the FinFET transistor M_{FIN2} shown in FIG. 2. However, each of the FinFET transistor M_{FINA} and the FinFET transistor M_{FINB} includes a single fin. It is noted that the number of fins in each of the FinFET transistors M_{FINA} and M_{FINB} of the storage device 600 is not restricted. The FinFET transistor M_{FINA} includes a fin 612, a gate structure and two drain/source contact layers 662 and 666. The FinFET transistor M_{FINB} includes a fin 614, a gate structure and two drain/source contact layers 664 and 668. The gate structure includes two gate dielectric layers 622 and 624 and three conductive layers 632, 634 and 642. The gate dielectric layers 622 and 624 cover the top surfaces and the lateral surfaces of the central region of the fins 612 and 614, respectively. The conductive layer 632 covers the gate dielectric layer 632, and the conductive layer 634 covers the gate dielectric layer 634. The conductive layer 642 covers the conductive layer 632 and the conductive layer 634. The conductive layer 642 is a shared conductive layer. That is, the gate conductive layer of the FinFET transistor M_{FINA} and M_{FINB} is formed by the three conductive layers 632, 634 and 642, and the conductive layers 642 is shared by the FinFET transistor M_{FINA} and M_{FINB}. The conductive layers 632 and 634 are work function metal layers. For example, the material of the conductive layers 632 and the conductive layer 634 are titanium nitride (TiN), tantalum nitride (TaN), or titanium-aluminum alloy (TiAl). The conductive layer 642 may be of the same material as the conductive layer 632 and 634.

The conducting line 645 is formed on the first side of the gate structure. In addition, the conducting line 645 is electrically connected with the first side of the conductive layer 642. The conducting line 647 is formed on the second side of the gate structure. In addition, the conducting line 647 is electrically connected with the second side of the conductive layer 642. Similarly, a conducting line 661 is formed to be electrically connected with a drain/source contact layer 662, a conducting line 665 is formed to be electrically connected with a drain/source contact layer 666, a conducting line 663 is formed to be electrically connected with a drain/source contact layer 664, and a conducting line 667 is formed to be electrically connected with a drain/source contact layer 668.

In accordance with a feature of the present invention, the electromigration mechanism is used to perform the program action. When the program action is performed, two different voltages are respectively provided to the two conducting lines 645 and 647. Consequently, a program current is generated in the region between the two conducting lines 645 and 647. Since electrons in the program current flow through the conductive layers 632, 634 and 642, the conductive layer 632 gradually migrates in the direction opposite to the electric field. In other words, the thickness of the conductive layer 632 is subject to a change. The use of the electromigration mechanism results in the thickness change of the work function metal layer. Consequently, the threshold voltage of the FinFET transistor M_{FINA} is changed.

Furthermore, when the program action is performed, no bias voltage is provided to the drain/source contact layers 662 and 666 of the FinFET transistor M_{FINA} and the drain/source contact layers 664 and 668 of the FinFET transistor M_{FINB}. In other words, when the program action is performed, the conducting lines 661, 665, 663 and 667 are in a floating state.

FIG. 8A schematically illustrate associated bias voltages for performing the program action on the storage device according to the second embodiment of the present invention. Before the program action is performed, the storage device 600 is in the unprogrammed state. When the program action is performed, two different voltages are respectively provided to the two conducting lines 645 and 647. For example, a program voltage V_{PGM} is provided to the conducting line 645, and a ground voltage GND is provided to the conducting line 647. Consequently, the voltage difference between the two conducting lines 645 and 647 is equal to the program voltage V_{PGM}. Under this circumstance, the conducting line 645 is regarded as the anode, and the conducting line 647 is regarded as the cathode. Consequently, the program current I_{PGM} flows through the conductive layers 632, 634 and 642.

As shown in FIG. 8A, the program current I_{PGM} indicated by the dotted line flows from the conducting line 645 to the conducting line 647 through the conductive layers 632, 634 and 642. Generally, the electromigration starts from the cathode (i.e., the conducting line 647). Due to the electromigration mechanism, the metal ions in the conductive layers 632 and 642 close to the cathode migrate in the opposite direction of the electric field (i.e., to the right). After the program action is completed, the thickness of the conductive layer 632 on the left side and indicated by the slash lines becomes thinner. Consequently, the threshold voltage of the FinFET transistor M_{FINA} is changed, and the storage state of the storage device 600 is changed to the programmed state. For example, before the program action, the threshold voltage of each of the FinFET transistor M_{FINA} and the FinFET transistor M_{FINB} is 0.5V. After the program action is completed, the threshold voltage of the FinFET transistor M_{FINA} is changed to 0.3V, but the threshold voltage of the FinFET transistor M_{FINB} is maintained at 0.5V. In some embodiments, after the program action is completed, the thickness of the conductive layer 634 on the left side and/or the right side may become thicker, and the threshold voltage of the FinFET transistor M_{FINB} is increased and is higher than 0.5V.

In an embodiment, when the program current I_{PGM} is greater than 100 microamperes (μA), the threshold voltage of the FinFET transistor M_{FINA} is changed by about 0.2˜0.3V. Since the resistance values of the conductive layers 632, 634 and 642 are very low, the program voltage V_{PGM} is very low. For example, the program voltage V_{PGM} of about 1.5V to 2.5V is feasible for the program action. When compared with the program action of the conventional non-volatile memory requiring a higher program voltage (e.g., 8V˜12V), the storage device 600 of the present invention are more advantageous. For example, the program voltage and the program current are lower. In other words, it is not necessary to provide such high program voltage V_{PGM} to the non-volatile memory with the storage device 600 of the present invention. Since there is no need to design a charge pump for generating a higher program voltage V_{PGM} in the non-volatile memory, the overall layout area of the non-volatile memory can be greatly reduced.

FIG. 8B and FIG. 8C schematically illustrate associated bias voltages for performing a read action on the storage device according to the second embodiment of the present invention. In FIG. 8B, the storage device 600 is in the unprogrammed state. For example, the threshold voltage of the FinFET transistor M_{FINA} is 0.5V, and the threshold voltage of the FinFET transistor M_{FINB} is 0.5V. In FIG. 8C, the storage device 600 is in the programmed state. For example, the threshold voltage of the FinFET transistor M_{FINA} is 0.3V, and the threshold voltage of the FinFET transistor M_{FINB} is 0.5V.

When a read action is performed on the storage device 600, the same control voltage V_{CTRL} is provided to the two conducting lines 645 and 647, and no current is generated between the two conducting lines 645 and 647. In addition, two different voltages are simultaneously provided to the two conducting lines 661 and 665, and two different voltages are simultaneously provided to the two conducting lines 663 and 667. For example, a read voltage V_{RD} is provided to the conducting lines 661 and 663, and the ground voltage GND is provided to the conducting lines 665 and 667. Consequently, the voltage difference between the two conducting lines 661 and 665 is equal to the read voltage V_{RD}, and the voltage difference between the two conducting lines 663 and 667 is also equal to the read voltage V_{RD}. For example, the read voltage V_{RD} is 1.0V. In some embodiment, when a read action is performed, at least one of the conducting lines 645 and 647 receives the control voltage V_{CTRL}.

When the read action is performed, the control voltage V_{CTRL} is set to 0.4V, and the control voltage V_{CTRL} is provided to the two conducting lines 645 and 647, and no current is generated between the two conducting lines 645 and 647. In FIG. 8B, the control voltage V_{CTRL} is lower than the threshold voltage of the FinFET transistor M_{FINA} (0.5V), and the control voltage V_{CTRL} is lower than the threshold voltage of the FinFET transistor M_{FINB} (0.5V). Consequently, the FinFET transistor M_{FINA} and the FinFET transistor M_{FINB} are turned off. Under this circumstance, the read current I_{RDA} between the two conducting lines 661 and 665 is very low (nearly zero), and the read current I_{RDB} between the two conducting lines 663 and 667 is very low (nearly zero). In FIG. 8C, the control voltage V_{CTRL} is higher than the threshold voltage of the FinFET transistor M_{FINA} (0.3V), but the control voltage V_{CTRL} is lower than the threshold voltage of the FinFET transistor M_{FINB} (0.5V). Consequently, the FinFET transistor M_{FINA} is turned on, and the FinFET transistor M_{FINB} is turned off. Under this circumstance, the read current I_{RDA} generated by the FinFET transistor M_{FINA} is higher. The read current I_{RDA} flows from the conducting line 661 to the conducting line 665 through the drain/source contact layer 662, the channel region of the FinFET transistor M_{FINA} and the drain/source contact layer 666. Since the FinFET transistor M_{FINB} is turned off, the read current I_{RDB} between the two conducting lines 663 and 667 is very low (nearly zero).

Furthermore, the non-volatile memory is equipped with a sensing circuit (not shown). The sensing circuit receives the two read currents the read current I_{RDA} and the read current I_{RDB}. In addition, the sensing circuit determines the storage state of the storage device according to the difference between the read current I_{RDA} and the read current I_{RDB}. If the difference between the read current I_{RDA} and the read current I_{RDB} is lower than a specified value, the sensing circuit determines that the storage device is in the unprogrammed state. Whereas, if the difference between the read current I_{RDA} and the read current I_{RDB} is higher than the specified value, the sensing circuit determines that the storage device is in the programmed state. In FIG. 8B, the read current I_{RDA} generated by the FinFET transistor M_{FINA} and the read current I_{RDB} generated by the FinFET transistor M_{FINB} are very low (nearly zero). Consequently, the sensing circuit determines that the storage device 600 is in the unprogrammed state. In FIG. 8C, the read current I_{RDA} generated by the FinFET transistor M_{FINA} is higher, and the read current I_{RDB} generated by the FinFET transistor M_{FINB} is very low (nearly zero). Consequently, the sensing circuit determines that the storage device 600 is in the programmed state.

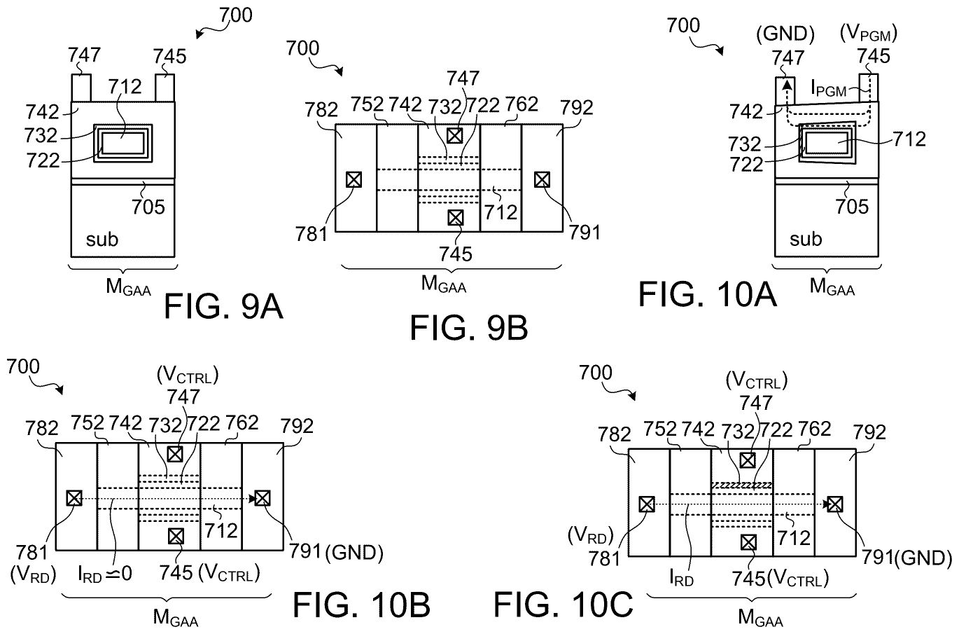

FIG. 9A is a schematic cross-sectional view illustrating the gate structure of an enhanced electromigration storage device according to a third embodiment of the present invention. FIG. 9B is a schematic top view illustrating the enhanced electromigration storage device according to the third embodiment of the present invention. The enhanced electromigration storage device 700 is included in a memory cell of the non-volatile memory. For brevity, the enhanced electromigration storage device 700 is referred hereinafter to as a storage device 700.

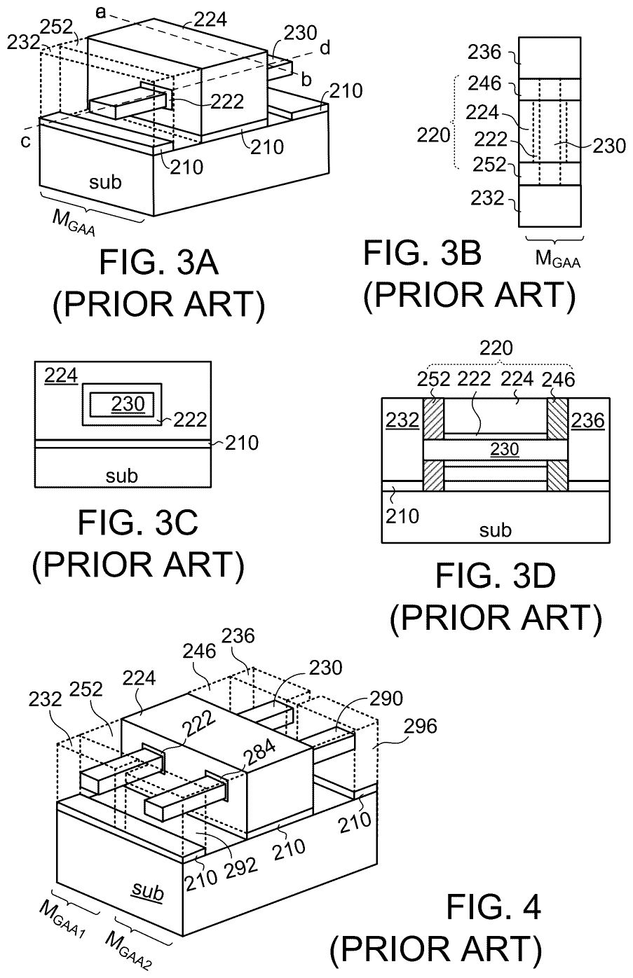

In this embodiment, the storage device 700 includes a GAA transistor M_{GAA} and two conducting lines 745 and 747. The GAA transistor M_{GAA} is located over a semiconductor substrate sub and an isolation layer 705. The structure of the GAA transistor M_{GAA} is similar to that of the GAA transistor M_{GAA} shown in FIG. 3C. The GAA transistor M_{GAA} includes a single nanowire 712. It is noted that the number of nanowires in the GAA transistor M_{GAA} of the storage device 700 is not restricted. The GAA transistor M_{GAA} includes two drain/source structures 782 and 792, a gate structure and a nanowire 712. The gate structure of the GAA transistor M_{GAA} includes two spacers 752 and 762, a gate dielectric layer 722 and two conductive layers 732 and 742. The gate dielectric layer 722 surrounds the central region of the nanowire 712. The conductive layer 732 surrounds the gate dielectric layer 722. The conductive layer 742 surrounds the conductive layer 732. That is, the gate conductive layer of the GAA transistor M_{GAA} is formed by the two conductive layers 732 and 742. The conductive layer 732 is a work function metal layer. For example, the material of the conductive layers 732 is titanium nitride (TiN), tantalum nitride (TaN), or titanium-aluminum alloy (TiAl). The conductive layer 742 may be of the same material as the conductive layer 732.

The conducting line 745 is formed on the first side of the gate structure. In addition, the conducting line 745 is electrically connected with the first side of the conductive layer 742. The conducting line 747 is formed on the second side of the gate structure. In addition, the conducting line 747 is electrically connected with the second side of the conductive layer 742. Similarly, a conducting line 781 is formed to be electrically connected with the drain/source structure 782, and a conducting line 791 is formed to be electrically connected with a drain/source structure 792.

In accordance with a feature of the present invention, the electromigration mechanism is used to perform the program action. When the program action is performed, two different voltages are respectively provided to the two conducting lines 745 and 747. Consequently, a program current is generated in the region between the two conducting lines 745 and 747. Since electrons in the program current flow through the conductive layers 742 and 732, the conductive layer 732 gradually migrates in the direction opposite to the electric field. In other words, the thickness of the conductive layer 732 is subject to a change. The use of the electromigration mechanism results in the thickness change of the work function metal layer. Consequently, the threshold voltage of the GAA transistor M_{GAA} is changed.

Furthermore, when the program action is performed, no bias voltage is provided to the drain/source structures 782 and 792. In other words, when the program action is performed, the conducting line 781 and the conducting line 791 are in a floating state.

FIG. 10A schematically illustrate associated bias voltages for performing the program action on the storage device according to the second embodiment of the present invention. Before the program action is performed, the storage device 700 is in the unprogrammed state. When the program action is performed, two different voltages are respectively provided to the two conducting lines 745 and 747. For example, a program voltage V_{PGM} is provided to the conducting line 745, and a ground voltage GND is provided to the conducting line 747. Consequently, the voltage difference between the two conducting lines 745 and 747 is equal to the program voltage V_{PGM}. Under this circumstance, the conducting line 745 is regarded as the anode, and the conducting line 747 is regarded as the cathode. Consequently, the program current I_{PGM} flows through the conductive layers 732 and 742.

As shown in FIG. 10A, the program current I_{PGM} indicated by the dotted line flows from the conducting line 745 to the conducting line 747 through the conductive layers 732 and 742. Generally, the electromigration starts from the cathode (i.e., the conducting line 747). Due to the electromigration mechanism, the metal ions in the conductive layers 732 and 742 close to the cathode migrate in the opposite direction of the electric field (i.e., to the right). After the program action is completed, the thickness of the conductive layer 732 on the left side and indicated by the slash lines becomes thinner. Consequently, the threshold voltage of the GAA transistor M_{GAA} is changed, and the storage state of the storage device 700 is changed to the programmed state. For example, before the program action, the threshold voltage of the GAA transistor M_{GAA} is 0.5V. After the program action is completed, the threshold voltage of the GAA transistor M_{GAA} is changed to 0.3V. In some embodiments, after the program action is completed, the thickness of the conductive layer 732 on the right side may become thicker.

In an embodiment, when the program current I_{PGM} is greater than 100 microamperes (μA), the threshold voltage of the GAA transistor M_{GAA} is changed by about 0.2˜0.3V. Since the resistance values of the conductive layers 732 and 742 are very low, the program voltage V_{PGM} is very low. For example, the program voltage V_{PGM} of about 1.5V to 2.5V is feasible for the program action. When compared with the program action of the conventional non-volatile memory requiring a higher program voltage (e.g., 8V˜12V), the storage device 700 of the present invention are more advantageous. For example, the program voltage and the program current are lower. In other words, it is not necessary to provide such high program voltage V_{PGM} to the non-volatile memory with the storage device 700 of the present invention. Since there is no need to design a charge pump for higher program voltage V_{PGM} in the non-volatile memory, the overall layout area of the non-volatile memory can be greatly reduced.

FIG. 10B and FIG. 10C schematically illustrate associated bias voltages for performing a read action on the storage device according to the third embodiment of the present invention. In FIG. 10B, the storage device 700 is in the unprogrammed state. For example, the threshold voltage of the GAA transistor M_{GAA} is 0.5V. In FIG. 10C, the storage device 700 is in the programmed state. For example, the threshold voltage of the GAA transistor M_{GAA} is 0.3V.

When a read action is performed on the storage device 700, the same control voltage V_{CTRL} is provided to the two conducting lines 745 and 747, and no current is generated between the two conducting lines 745 and 747. In addition, two different voltages are simultaneously provided to the two conducting lines 781 and 791. For example, a read voltage V_{RD} is provided to the conducting line 781, and the ground voltage GND is provided to the conducting line 791. Consequently, the voltage difference between the two conducting lines 781 and 791 is equal to the read voltage V_{RD}. For example, the read voltage V_{RD} is 1.0V. In some embodiment, when a read action is performed, at least one of the conducting lines 781 and 791 receives the control voltage V_{CTRL}.

When the read action is performed, the control voltage V_{CTRL} is set to 0.4V, and the control voltage V_{CTRL} is provided to the two conducting lines 745 and 747, and no current is generated between the two conducting lines 745 and 747. In FIG. 10B, the control voltage V_{CTRL} is lower than the threshold voltage of the GAA transistor M_{GAA} (0.5V). Consequently, the GAA transistor M_{GAA} is turned off, and the read current I_{RD} between the two conducting lines 781 and 791 is very low (nearly zero). In FIG. 10C, the control voltage V_{CTRL} is higher than the threshold voltage of the GAA transistor M_{GAA} (0.3V). Consequently, the GAA transistor M_{GAA} is turned on, and the read current I_{RD} generated by the GAA transistor M_{GAA} is higher. The read current I_{RD} flows from the conducting line 781 to the conducting line 791 through the drain/source structure 782, the channel region of the GAA transistor M_{GAA} and the drain/source structure 792. That is to say, the storage state of the storage device 700 can be determined according to the magnitude of the read current I_{RD}.

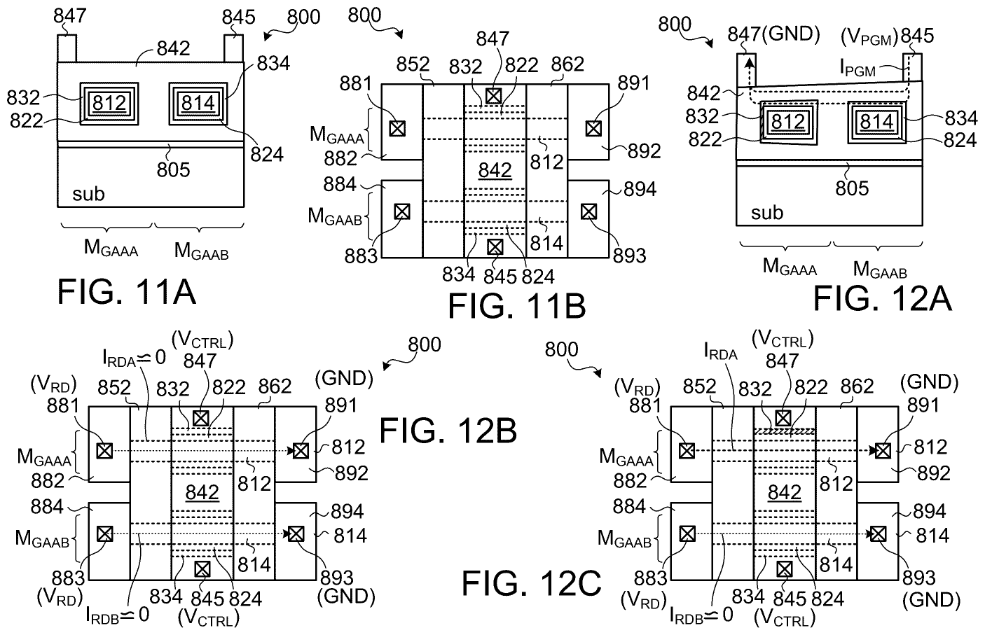

FIG. 11A is a schematic cross-sectional view illustrating the gate structure of an enhanced electromigration storage device according to a fourth embodiment of the present invention. FIG. 11B is a schematic top view illustrating the enhanced electromigration storage device according to the fourth embodiment of the present invention. In this embodiment, the storage device 800 includes two GAA transistors M_{GAAA} and M_{GAAB}. Furthermore, the storage device 800 is designed in a differential memory cell of the non-volatile memory.

In this embodiment, the storage device 800 includes the GAA transistor M_{GAAA}, the GAA transistor M_{GAAB}, and two conducting lines 845 and 847. The GAA transistor M_{GAAA} and the GAA transistor M_{GAAB} are located over a semiconductor substrate sub and an isolation layer 805. The structures of the GAA transistor M_{GAAA} and the GAA transistor M_{GAAB} are similar to those of the GAA transistor M_{GAA1} and the GAA transistor M_{GAA2} shown in FIG. 4. Each of the GAA transistor M_{GAAA} and the GAA transistor M_{GAAB} includes a single nanowire. It is noted that the number of nanowires in each of the GAA transistors M_{GAAA} and M_{GAAB} of the storage device 800 is not restricted. The GAA transistor M_{GAAA} includes a nanowire 812, a gate structure and two drain/source structures 882 and 892. The gate structure of the GAA transistor M_{GAAA} includes two spacers 852 and 862, a gate dielectric layer 822 and two conductive layers 832 and 842. The GAA transistor M_{GAAB} includes a nanowire 814, a gate structure and two drain/source structures 884 and 894. The gate structure of the GAA transistor M_{GAAB} includes the two spacers 852 and 862, a gate dielectric layer 824 and two conductive layers 834 and 842. The conductive layer 842 is a shared conductive layer. The gate dielectric layers 822 and 824 surround the central region of the nanowires 812 and 814, respectively. The conductive layer 832 surrounds the gate dielectric layer 822, and the conductive layer 834 surrounds the gate dielectric layer 824. The conductive layer 842 surrounds the conductive layer 832 and the conductive layer 834. The conductive layers 832 and 834 are work function metal layers. For example, the material of the conductive layers 832 and the conductive layer 834 are titanium nitride (TiN), tantalum nitride (TaN), or titanium-aluminum alloy (TiAl). The conductive layer 842 may be of the same material as the conductive layer 832 and 834.

The conducting line 845 is formed on the first side of the gate structure. In addition, the conducting line 845 is electrically connected with the first side of the conductive layer 842. The conducting line 847 is formed on the second side of the gate structure. In addition, the conducting line 847 is electrically connected with the second side of the conductive layer 842. Similarly, a conducting line 881 is formed to be electrically connected with the drain/source structure 882, a conducting line 891 is formed to be electrically connected with the drain/source structure 892, a conducting line 883 is formed to be electrically connected with the drain/source structure 884, and a conducting line 893 is formed to be electrically connected with the drain/source structure 894.

In accordance with a feature of the present invention, the electromigration mechanism is used to perform the program action. When the program action is performed, two different voltages are respectively provided to the two conducting lines 845 and 847. Consequently, a program current is generated in the region between the two conducting lines 845 and 847. Since electrons in the program current flow through the conductive layers 832, 834 and 842, the conductive layer 832 gradually migrates in the direction opposite to the electric field. In other words, the thickness of the conductive layer 832 is subject to a change. The use of the electromigration mechanism results in the thickness change of the work function metal layer. Consequently, the threshold voltage of the GAA transistor M_{GAAA} is changed.

Furthermore, when the program action is performed, no bias voltage is provided to the drain/source structures 882 and 892 of the GAA transistor M_{GAAA} and the drain/source structures 884 and 894 of the GAA transistor M_{GAAB}. In other words, when the program action is performed, the conducting lines 881, 891, 883 and 893 are in a floating state.

FIG. 12A schematically illustrate associated bias voltages for performing the program action on the storage device according to the fourth embodiment of the present invention. Before the program action is performed, the storage device 800 is in the unprogrammed state. When the program action is performed, two different voltages are respectively provided to the two conducting lines 845 and 847. For example, a program voltage V_{PGM} is provided to the conducting line 845, and a ground voltage GND is provided to the conducting line 847. Consequently, the voltage difference between the two conducting lines 845 and 847 is equal to the program voltage V_{PGM}. Under this circumstance, the conducting line 845 is regarded as the anode, and the conducting line 847 is regarded as the cathode. Consequently, the program current I_{PGM} flows through the conductive layers 832, 834 and 842.

As shown in FIG. 12A, the program current I_{PGM} indicated by the dotted line flows from the conducting line 845 to the conducting line 847 through the conductive layers 832, 834 and 842. Generally, the electromigration starts from the cathode (i.e., the conducting line 847). Due to the electromigration mechanism, the metal ions in the conductive layers 832 and 842 close to the cathode migrate in the opposite direction of the electric field (i.e., to the right). After the program action is completed, the thickness of the conductive layer 832 on the left side and indicated by the slash lines becomes thinner. Consequently, the threshold voltage of the GAA transistor M_{GAAA} is changed, and the storage state of the storage device 800 is changed to the programmed state. For example, before the program action, the threshold voltage of each of the GAA transistor M_{GAAA} and the GAA transistor M_{GAAB} is 0.5V. After the program action is completed, the threshold voltage of the GAA transistor M_{GAAA} is changed to 0.3V, but the threshold voltage of the GAA transistor M_{GAAB} is maintained at 0.5V. In some embodiments, after the program action is completed, the thickness of the conductive layer 834 on the left side and/or the right side may become thicker, and the threshold voltage of the GAA transistor M_{GAAB} is increased and is higher than 0.5V.

In an embodiment, when the program current I_{PGM} is greater than 100 microamperes (μA), the threshold voltage of the GAA transistor M_{GAAA} is changed by about 0.2˜0.3V. Since the resistance values of the conductive layers 832, 834 and 842 are very low, the program voltage V_{PGM} is very low. For example, the program voltage V_{PGM} of about 1.5V to 2.5V is feasible for the program action. When compared with the program action of the conventional non-volatile memory requiring a higher program voltage (e.g., 8V˜12V), the storage device 800 of the present invention are more advantageous. For example, the program voltage and the program current are lower. In other words, it is not necessary to provide such high program voltage V_{PGM} to the non-volatile memory with the storage device 800 of the present invention. Since there is no need to design a charge pump for the higher program voltage V_{PGM} in the non-volatile memory, the overall layout area of the non-volatile memory can be greatly reduced.

FIG. 12B and FIG. 12C schematically illustrate associated bias voltages for performing a read action on the storage device according to the fourth embodiment of the present invention. In FIG. 12B, the storage device 800 is in the unprogrammed state. For example, the threshold voltage of the GAA transistor M_{GAAA} is 0.5V, and the threshold voltage of the GAA transistor M_{GAAB} is 0.5V. In FIG. 12C, the storage device 800 is in the programmed state. For example, the threshold voltage of the GAA transistor M_{GAAA} is 0.3V, and the threshold voltage of the GAA transistor M_{GAAB} is 0.5V.

When a read action is performed on the storage device 800, the same control voltage V_{CTRL} is provided to the two conducting lines 845 and 847 or one of the conducting lines 845 and 847. In addition, two different voltages are simultaneously provided to the two conducting lines 881 and 891, and two different voltages are simultaneously provided to the two conducting lines 883 and 893. For example, a read voltage V_{RD} is provided to the conducting lines 881 and 883, and the ground voltage GND is provided to the conducting lines 891 and 893. Consequently, the voltage difference between the two conducting lines 881 and 891 is equal to the read voltage V_{RD}, and the voltage difference between the two conducting lines 883 and 893 is also equal to the read voltage V_{RD}. For example, the read voltage V_{RD} is 1.0V.

When the read action is performed, the control voltage V_{CTRL} is set to 0.4V, and the control voltage V_{CTRL} is provided to the two conducting lines 845 and 847. In FIG. 12B, the control voltage V_{CTRL} is lower than the threshold voltage of the GAA transistor M_{GAAA} (0.5V), and the control voltage V_{CTRL} is lower than the threshold voltage of the GAA transistor M_{GAAB} (0.5V). Consequently, the GAA transistor M_{GAAA} and the GAA transistor M_{GAAB} are turned off. Under this circumstance, the read current I_{RDA} between the two conducting lines 881 and 891 is very low (nearly zero), and the read current I_{RDB} between the two conducting lines 883 and 893 is very low (nearly zero). In FIG. 12C, the control voltage V_{CTRL} is higher than the threshold voltage of the GAA transistor M_{GAAA} (0.3V), but the control voltage V_{CTRL} is lower than the threshold voltage of the GAA transistor M_{GAAB} (0.5V). Consequently, the GAA transistor M_{GAAA} is turned on, and the GAA transistor M_{GAAB} is turned off. Under this circumstance, the read current I_{RDA} generated by the GAA transistor M_{GAAA} is higher. The read current I_{RDA} flows from the conducting line 881 to the conducting line 891 through the drain/source structure 882, the channel region of the GAA transistor M_{GAAA} and the drain/source structure 892. Since the GAA transistor M_{GAAB} is turned off, the read current I_{RDB} between the two conducting lines 883 and 893 is very low (nearly zero). That is to say, the storage state of the storage device 800 can be determined according to the magnitude of the two read currents I_{RDA} and I_{RDB}.

The structures of the storage devices 500, 600, 700 and 800 of the above embodiments may be further modified to enhance the electromigration efficacy. Consequently, the difference in the threshold voltage of the transistor before and after programmed will be increased. A modified structure of the storage device 500 of the first embodiment will be described as follows. Of course, the concepts of the modifications of the storage device 500 of the first embodiment can be applied to the modifications of the storage devices 600, 700 and 800.

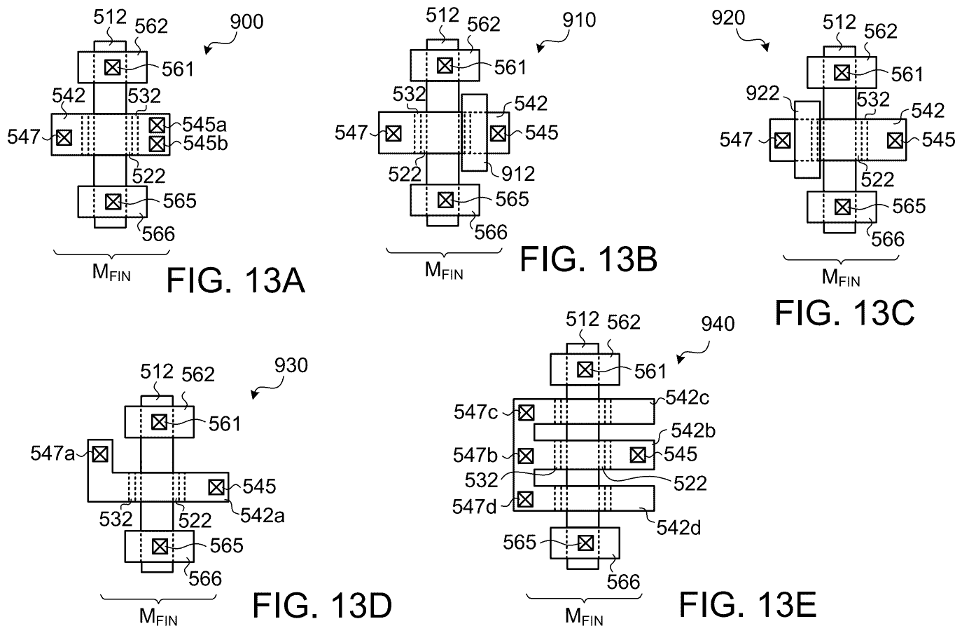

FIG. 13A is a schematic top view illustrating an enhanced electromigration storage device according to a fifth embodiment of the present invention. When compared with the storage device 500 of the first embodiment, the cross-sectional areas of the contact holes connected to the first side and the second side of the conductive layer 542 in the storage device 900 of this embodiment are different. That is, the cross-sectional area of the contact hole serving as the anode is larger than the cross-sectional area of the contact hole serving as the cathode. For example, assuming that the cross-sectional area of each contact hole is identical, the number of conducting lines for the anode is designed to be larger than the number of conducting lines for the cathode.

As shown in FIG. 13A, two conducting lines 545a and 545b are electrically connected with the first side of the conductive layer 542. When the program action is performed, the two conducting lines 545a and 545b are served as anodes and receive the program voltage V_{PGM}. Furthermore, a single conducting line 547 is electrically connected with the second side of the conductive layer 542. When the program action is performed, the conducting line 547 is served as a cathode and receives the ground voltage (GND). Consequently, during the program action, the total program current inputted into the anode will be concentrated on the cathode, making the electromigration phenomenon more likely to occur. In this way, the difference in the threshold voltage of the transistor FinFET transistor M_{FIN} before and after programmed will be increased. Like the above embodiments, when the read action is performed, all conducting lines 545a, 545b and 547 connected with the conductive layer 542 receive the same control voltage V_{CTRL}.

Similarly, the concepts of the modifications of the storage device 900 of this embodiment can be applied to the modifications of the storage devices 600, 700 and 800 of the above embodiments.

FIG. 13B is a schematic top view illustrating an enhanced electromigration storage device according to a sixth embodiment of the present invention. When compared with the storage device 500 of the first embodiment, the storage device 910 of this embodiment is additionally equipped with a heat dissipation metal layer 912. The heat dissipation metal layer 912 is located over the first side of the conductive layer 542. In addition, the heat dissipation metal layer 912 is in contact with the conductive layer 542. In some embodiments, the heat dissipation metal layer 912 may be metals or alloys to enhance grain boundaries.

When the program action is performed, a program current I_{PGM} flows through the conductive layers 542 and 532, causing the FinFET transistor M_{FIN} to generate heat. Since the heat dissipation metal layer 912 is located over the first side of the conductive layer 542, the heat generated by the first side of the conductive layer 542 can be dissipated quickly. Consequently, the heat gradient between the first side and the second side of the conductive layer 542 is increased and may produce thermal stress, and the EM efficiency is further enhanced. In this way, the difference in the threshold voltage of the transistor FinFET transistor M_{FIN} before and after programmed will be increased.

Similarly, the concepts of the modifications of the storage device 910 of this embodiment can be applied to the modifications of the storage devices 600, 700 and 800 of the above embodiments.

FIG. 13C is a schematic top view illustrating an enhanced electromigration storage device according to a seventh embodiment of the present invention. When compared with the storage device 500 of the first embodiment, the storage device 920 of this embodiment is additionally equipped with a heating layer 922. The heating layer 922 is located over the second side of the conductive layer 542, and the heating layer 922 is not in contact with the conductive layer 542. For example, the heating layer 922 is a resistance layer. The heating layer 922 may be the lower metal layer which closer to the substrate used for connections between transistors and other components in an electronic circuit layout (i.e., interconnection), for example, the heating layer 922 can be the first metal layer or the second metal layer above the storage device 920.

When the program action is performed, a program current I_{PGM} flows through the conductive layer 542, the conductive layer 532 and the heating layer 922, causing the FinFET transistor M_{FIN} to generate heat. Since the heating layer 922 is located over the second side of the conductive layer 542, the temperature at the second side of the conductive layer 542 is increased. Consequently, the heat gradient between the first side and the second side of the conductive layer 542 is increased and may produce thermal stress, and the EM efficiency is further enhanced. In this way, the difference in the threshold voltage of the transistor FinFET transistor M_{FIN} before and after programmed will be increased.

Similarly, the concepts of the modifications of the storage device 920 of this embodiment can be applied to the modifications of the storage devices 600, 700 and 800 of the above embodiments.

FIG. 13D is a schematic top view illustrating an enhanced electromigration storage device according to an eighth embodiment of the present invention. When compared with the storage device 500 of the first embodiment, the shape of the gate structure in the storage device 930 of the eighth embodiment is distinguished. In this embodiment, the gate structure is an L-shaped structure comprising a main branch and a sub-branch. The main branch covers the fin 512. The sub-branch is extended from a first side of the main branch and can be in parallel with the fin 512. The sub-branch and the main branch form a bend. Furthermore, a conducting line 547a is electrically connected with the conductive layer 542a corresponding to the sub-branch, and a conducting line 545 is electrically connected with the conductive layer 542a corresponding to the second side of the main branch.

When the program action is performed, a program current I_{PGM} is generated. The program current flowing through the turning point at the bend of the conductive layer 542a causes a current crowding phenomenon and may produce thermal stress, and the EM efficiency is further enhanced. In this way, the difference in the threshold voltage of the transistor FinFET transistor M_{FIN} before and after programmed will be increased.

Similarly, the concepts of the modifications of the storage device 930 of this embodiment can be applied to the modifications of the storage devices 600, 700 and 800 of the above embodiments.

FIG. 13E is a schematic top view illustrating an enhanced electromigration storage device according to a ninth embodiment of the present invention which illustrates another heat sink in cathode. When compared with the storage device 500 of the first embodiment, the shape of the gate structure in the storage device 940 of the ninth embodiment is distinguished. In this embodiment, the gate structure is an E-shaped (finger-type) structure comprising a main branch, a first sub-branch and a second sub-branch. The first sub-branch and the second sub-branch extend from the main branch and are located on both sides of the main branch. Parts of the first sub-branch and parts of the second sub-branch are in parallel with the main branch. The main branch covers the fin 512, and the first sub-branch and the second sub-branch also cover the fin 512. Furthermore, the gate structure includes the conductive layer 542b corresponding to the main branch, the conductive layer 542c corresponding to the first sub-branch, and the conductive layer 542d corresponding to the second sub-branch. The conducting line 545 is electrically connected with the conductive layer 542b corresponding to the first side of the main branch. The conducting line 547b is electrically connected with the conductive layer 542b corresponding to the second side of the main branch. Also, the conducting line 547c is electrically connected with the conductive layer 542c corresponding to the second side of the first sub-branch. The conducting line 547d is electrically connected with the conductive layer 542d corresponding to the second side of the second sub-branch.

When the program action is performed, a program current I_{PGM} flows through the conductive layer 542b and the conductive layer 532, causing the FinFET transistor M_{FIN} to generate heat and may produce thermal stress. The two sub-branches of the gate structure can enhance heat dissipation. Consequently, the heat gradient between the first side and the second side of the conductive layer 542b is increased, and the EM efficiency is further enhanced. In this way, the difference in the threshold voltage of the transistor FinFET transistor M_{FIN} before and after programmed will be increased.

Similarly, the concepts of the modifications of the storage device 940 of this embodiment can be applied to the modifications of the storage devices 600, 700 and 800 of the above embodiments.

From the above descriptions, the present invention provides an enhanced electromigration storage device for a non-volatile memory. When the program action is performed, two different voltages are simultaneously provided to the gate terminal of the FinFET transistor or the GAA transistor. Furthermore, the threshold of the FinFET transistor or the GAA transistor is changed according to the electromigration mechanism. Consequently, the storage device is selectively in the programmed state or the unprogrammed state. When the read action is performed, the same voltage is provided to the gate terminal of the FinFET transistor or the GAA transistor, and the storage state of the storage device is determined according to the read current generated by the FinFET transistor or the GAA transistor.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A storage device of a non-volatile memory, comprising:
a first fin field-effect transistor comprising a first fin, a gate structure, a first drain/source contact layer and a second drain/source contact layer, wherein the gate structure comprises a first gate dielectric layer, a first conductive layer and a second conductive layer, wherein a top surface and two lateral surfaces of a central region of the first fin are covered by the first gate dielectric layer, the first gate dielectric layer is covered by the first conductive layer, the first conductive layer is covered by the second conductive layer, the first drain/source contact layer is electrically contacted with a first side region of the first fin, and the second drain/source contact layer is electrically contacted with a second side region of the first fin;
a first conducting line located on a first side of the gate structure and electrically connected with a first side of the second conductive layer; and
a second conducting line located on a second side of the gate structure and electrically connected with a second side of the second conductive layer,
wherein when a program action is performed, the first conducting line receives a first voltage, the second conducting line receives a second voltage, and a program current flows from the first conducting line to the second conducting line through the first conductive layer and the second conductive layer, wherein the first voltage is higher than the second voltage,
wherein when a read action is performed, the first drain/source contact layer receives a third voltage, the second drain/source contact layer receives a fourth voltage, at least one of the first conducting line and the second conducting line receives a control voltage, and a first read current flows from the first drain/source contact layer to the second drain/source contact layer through a channel region of the first fin field-effect transistor, and a storage state of the storage device is determined by the first read current, wherein the third voltage is higher than the fourth voltage,
wherein a difference between the first voltage and the second voltage is equal to a program voltage, and a difference between the third voltage and the fourth voltage is equal to a read voltage.

2. The storage device as claimed in claim 1, wherein the first conductive layer is a work function metal layer, and a threshold voltage of the first fin field-effect transistor is determined according to a thickness of the work function metal layer.

3. The storage device as claimed in claim 2, wherein the work function metal layer is made of titanium nitride (TiN), tantalum nitride (TaN), or titanium-aluminum alloy (TiAl).

4. The storage device as claimed in claim 2, wherein when the program action is performed, the program current flows through the first conductive layer, and a thickness of the first conductive layer is changed after the program action is performed, so that the threshold voltage of the first fin field-effect transistor is changed, and the threshold voltage is lower than the control voltage.

5. The storage device as claimed in claim 1, wherein the first conducting line is electrically connected with the second conductive layer through a first contact hole, and the second conducting line is electrically connected with the second conductive layer through a second contact hole, wherein a cross-sectional area of the first contact hole is larger than a cross-sectional area of the second contact hole.

6. The storage device as claimed in claim 1, wherein the storage device further comprises a third conducting line, and the third conducting line is electrically connected with the first side of the second conductive layer, wherein when the program action is performed, the first conducting line and the third conducting line receive the first voltage.

7. The storage device as claimed in claim 1, wherein the storage device further comprises a heat dissipation metal layer, wherein the heat dissipation metal layer is located over the first side of the second conductive layer, and the heat dissipation metal layer is in contact with the second conductive layer.

8. The storage device as claimed in claim 1, wherein the storage device further includes a heating layer, wherein the heating layer is located over the second side of the second conductive layer, and the heating layer is not in contact with the second conductive layer.

9. The storage device as claimed in claim 1, wherein the gate structure comprises a main branch and a sub-branch, wherein the main branch covers the first fin, the sub-branch is extended from a first side of the main branch, the second conducting line is electrically connected with the second conductive layer at the sub-branch, and the first conducting line is electrically connected with the second conductive layer at the a second side of the main branch.

10. The storage device as claimed in claim 1, wherein the gate structure comprises a main branch, a first sub-branch and a second sub-branch, wherein the first conducting line is electrically connected with the second conductive layer at a first side of the main branch, the second conducting line is electrically connected with the second conductive layer at a second side of the main branch, the main branch covers the first fin, the first sub-branch and the second sub-branch are extended from the second side of the main branch, and the first sub-branch and the second sub-branch cover the first fin.

11. The storage device as claimed in claim 1, further comprising a second fin field-effect transistor, wherein the second fin field-effect transistor comprises: a second fin, the gate structure, a third drain/source contact layer and a fourth drain/source contact layer, wherein the gate structure further comprises a second gate dielectric layer and a third conductive layer, wherein a top surface and two lateral surfaces of a central region of the second fin are covered by the second gate dielectric layer, the second gate dielectric layer is covered by the third conductive layer, the third conductive layer is covered by the second conductive layer, the third drain/source contact layer is electrically contacted with a first side region of the second fin, and the fourth drain/source contact layer is electrically contacted with a second side region of the second fin;
wherein when the read action is performed, the third drain/source contact layer receive the third voltage, the fourth drain/source contact layer receive the fourth voltage, and a second read current flows from the third drain/source contact layer to the fourth drain/source contact layer through a channel region of the second fin field-effect transistor, and the storage state is determined by the first read current and the second read current.

12. The storage device as claimed in claim 11, wherein when the program action is performed, the program current flows through the first conductive layer and the third conductive layer, a thickness of the first conductive layer is changed and a thickness of the third conductive layer is changed, so that a threshold voltage of the first fin field-effect transistor is changed and a threshold voltage of the second fin field-effect transistor is changed, so that the threshold voltage of the first fin field-effect transistor is lower than the control voltage, and the threshold voltage of the second fin field-effect transistor is higher than the control voltage.

13. A storage device for a non-volatile memory, comprising:
a first gate-all-around transistor comprising a first nanowire, a gate structure, a first drain/source structure and a second drain/source structure, wherein the gate structure comprises a first gate dielectric layer, a first conductive layer and a second conductive layer, wherein a central region of the first nanowire is surrounded by the first gate dielectric layer, the first gate dielectric layer is surrounded by the first conductive layer, the first conductive layer is surrounded by the second conductive layer, the first drain/source structure is electrically contacted with a first side region of the first nanowire, and the second drain/source structure is electrically contacted with a second side region of the first nanowire;
a first conducting line located on a first side of the gate structure and electrically connected with a first side of the second conductive layer; and
a second conducting line located on a second side of the gate structure and electrically connected with a second side of the second conductive layer,
wherein when a program action is performed, the first conducting line receives a first voltage, the second conducting line receives a second voltage, and a program current flows from the first conducting line to the second conducting line through the first conductive layer and the second conductive layer, wherein the first voltage is higher than the second voltage,
wherein when a read action is performed, the first drain/source structure receives a third voltage, the second drain/source structure receives a fourth voltage, at least one of the first conducting line and the second conducting line receive a control voltage, and a first read current flows from the first drain/source structure to the second drain/source structure through a channel region of the first gate-all-around transistor, and a storage state of the non-volatile memory device is determined by the first read current, wherein the third voltage is higher than the fourth voltage,
wherein a difference between the first voltage and the second voltage is equal to a program voltage, and a difference between the third voltage and the fourth voltage is equal to a read voltage.

14. The storage device as claimed in claim 13, wherein the first conductive layer is a work function metal layer, and a threshold voltage of the first gate-all-around transistor is determined according to a thickness of the work function metal layer.

15. The storage device as claimed in claim 14, wherein when the program action is performed, the program current flows through the first conductive layer, and a thickness of the first conductive layer is changed after the program action is performed, so that the threshold voltage of the first gate-all-around transistor is changed, and the threshold voltage is lower than the control voltage.

16. The storage device as claimed in claim 13, wherein the first conducting line is electrically connected with the second conductive layer through a first contact hole, and the second conducting line is electrically connected with the second conductive layer through a second contact hole, wherein a cross-sectional area of the first contact hole is larger than a cross-sectional area of the second contact hole.

17. The storage device as claimed in claim 13, wherein the storage device further comprises a third conducting line, and the third conducting line is electrically connected with the first side of the second conductive layer, wherein when the program action is performed, the first conducting line and the third conducting line receive the first voltage.

18. The storage device as claimed in claim 13, wherein the storage device further comprises a heat dissipation metal layer, wherein the heat dissipation metal layer is located over the first side of the second conductive layer, and the heat dissipation metal layer is in contact with the second conductive layer.

19. The storage device as claimed in claim 13, wherein the storage device further includes a heating layer, wherein the heating layer is located over the second side of the second conductive layer, and the heating layer is not in contact with the second conductive layer.

20. The storage device as claimed in claim 13, wherein the gate structure comprises a main branch and a sub-branch, wherein the main branch surrounds the first nanowire, the sub-branch is extended from a first side of the main branch, the second conducting line is electrically connected with the second conductive layer at the sub-branch, and the first conducting line is electrically connected with the second conductive layer at the a second side of the main branch.

21. The storage device as claimed in claim 13, wherein the gate structure comprises a main branch, a first sub-branch and a second sub-branch, wherein the first conducting line is electrically connected with the second conductive layer at a first side of the main branch, the second conducting line is electrically connected with the second conductive layer at a second side of the main branch, the main branch surrounds the first nanowire, the first sub-branch and the second sub-branch are extended from the second side of the main branch, and the first sub-branch and the second sub-branch surround the first nanowire.

22. The storage device as claimed in claim 13, further comprising a second gate-all-around transistor, wherein the second gate-all-around transistor comprises: a second nanowire, the gate structure, a third drain/source structure and a fourth drain/source structure, wherein the gate structure further comprises a second gate dielectric layer and a third conductive layer, wherein a central region of the second nanowire is surrounded by the second gate dielectric layer, the second gate dielectric layer is surrounded by the third conductive layer, the third conductive layer is surrounded by the second conductive layer, the third drain/source structure is electrically contacted with a first side region of the second nanowire, and the fourth drain/source structure is electrically contacted with a second side region of the second nanowire,
wherein when the read action is performed, the third drain/source structure receive the third voltage, the fourth drain/source structure receive a fourth voltage, and a second read current flows from the third drain/source structure to the fourth drain/source structure through a channel region of the second gate-all-around transistor, and the storage state is determined by the first read current and the second read current.
